(19) United States
(12) Patent Application Publication
(10) Pub. No.: US 2008/0219312 A1
(43) Pub. Date: Sep. 11, 2008

(54) QUANTUM CASCADE LASER DEVICE

(75) Inventors: Atsushi SUGIYAMA, Hamamatsu-shi (JP); Takahide OCHIAI, Hamamatsu-shi (JP); Kazuue FUJITA, Hamamatsu-shi (JP); Naota AKIKUSA, Hamamatsu-shi (JP); Tadataka EDAMURA, Hamamatsu-shi (JP); Shinichi FURUTA, Hamamatsu-shi (JP)

Correspondence Address: DRINKER BIDDLE & REATH (DC), 1500 K STREET, N.W., SUITE 1100, WASHINGTON, DC, 20005-1209, US

(73) Assignee: HAMAMATSU PHOTONICS K.K., Shizuoka (JP)

(21) Appl. No.: 12/043,331

(22) Filed: Mar. 6, 2008

(30) Foreign Application Priority Data
Mar. 7, 2007 (JP) P2007-057666

(51) Int. Cl. H01S 5/30

(52) U.S. Cl. 372/46.01

(57) ABSTRACT

In a quantum cascade laser device 1, a laminate structure 11 is formed into a stripe shape along a predetermined direction on a principal surface at one side of a substrate 10, and insulating layers 15 are formed on bilateral sides of the laminate structure 11, and an insulating layer 16 and a metal layer 17 are formed in sequence on the laminate structure 11 and the insulating layers 15. The laminate structure 11 is formed such that a cladding layer 12, an active layer 13, and a cladding layer 14 are formed in sequence from the side of the substrate 10. In the active layer 13, light emitting layers and injection layers are alternately laminated, and the active layer 13 generates light due to intersubband electron transition in a quantum well structure. A shape in a cross section of the laminate structure 11 perpendicular to the direction in which the laminate structure 11 is provided to extend is formed into a rectangle or an inverted mesa shape. In accordance therewith, it is possible to realize a quantum cascade laser device having high slope efficiency, and being capable of stably realizing a single transverse mode operation.

### BACKGROUND OF THE INVENTION

1. Field of the Invention

The present invention relates to a quantum cascade laser device.

2. Related Background Art

A quantum cascade laser device is a monopolar type element, in which a laminate structure including an active layer in which light emitting layers and injection layers are alternately laminated is formed on a principal surface of a substrate, and which is capable of generating light due to intersubband electron transition in a quantum well structure in the active layer. A quantum cascade laser device is capable of realizing high-efficiency and high-power operation due to an active layer in which light emitting layers and injection layers are alternately disposed in a multistage configuration and in a cascade manner, and is expected as a high-performance semiconductor light source in a region from mid-infrared to THz wavelengths.

In a quantum cascade laser device, when a voltage is applied between the upper and lower layers in the laminate structure, transition of electrons is made from an upper level to a lower level in a quantum level structure of a light emitting layer, and light having a wavelength corresponding to an energy difference between the levels is generated at the time of the electron transition. The electrons are made to carry out transition to the lower level of the light emitting layer, move to an upper level of the next light emitting layer through an adjacent injection layer, and in the same way as in the emitting layer as well, transition thereof is made from the upper level to a lower level, and light at a wavelength corresponding to an energy difference between the levels is generated at the time of the electron transition. In this way, light is generated in each light emitting layer.

In a quantum cascade laser device disclosed in Patent Document 1 (Japanese Translation of PCT International Application No. 2003-526214), a laminate structure is formed into a stripe shape along a predetermined direction on a principal surface of a substrate, and the end faces of the laminate structure in the predetermined direction serve as mirrors configuring a laser resonator. Further, in the quantum cascade laser device disclosed in the document, a shape at a cross section of the laminate structure perpendicular to the predetermined direction is formed into a normal mesa shape.
Patent document 1: Japanese Translation of PCT International Application (Kohyo) No. 2003-526214

### SUMMARY OF THE INVENTION

The quantum cascade laser device disclosed in Patent Document 1 is formed such that a shape in a cross section of the laminate structure is a normal mesa shape, and a width of the lower part (the substrate side) is made wider than a width of the upper part of the laminate structure. In accordance therewith, this device is not efficient in its current confinement, and which leads to low slope efficiency (a ratio (ΔP/ΔI) of a light output increment ΔP with respect to a current increment ΔI during laser oscillation). Further, because a width of a light emitting layer is broadened, it is difficult to achieve single transverse mode operation.

The present invention has been made in order to solve the above-described problem, and it is an object of the present invention to provide a quantum cascade laser device which has high slope efficiency, and is capable of stably realizing a single transverse mode operation.

A quantum cascade laser device according to the present invention includes a substrate, and a laminate structure including an active layer in which light emitting layers and injection layers are alternately laminated, and which generates light due to intersubband electron transition in a quantum well structure, and in the device, the laminate structure is formed in a stripe shape along a predetermined direction on a principal surface of the substrate, and a shape in a cross section of the laminate structure perpendicular to the predetermined direction is a rectangle or an inverted mesa shape, and insulating layers are formed on the principal surface of the substrate and on bilateral sides of the laminate structure.

In this way, because a cross-sectional shape of the laminate structure is a rectangle or an inverted mesa shape, the quantum cascade laser device according to the present invention has high slope efficiency, and is capable of stably realizing a single transverse mode operation. Further, because heat generated in the active layer during driving is radiated through the insulating layers, the radiation performance is improved.

The quantum cascade laser device according to the present invention has high slope efficiency, and is capable of stably achieving a single transverse mode operation.

The present invention will be more fully understood from the detailed description given hereinbelow and the accompanying drawings, which are given by way of illustration only and are not to be considered as limiting the present invention.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will be apparent to those skilled in the art from this detailed description.

### BRIEF DESCRIPTION OF THE DRAWINGS

FIG. 1 is a perspective view of a quantum cascade laser device 1 according to a first embodiment.

FIG. 2 is a schematic view for explanation of a configuration of an active layer 13 in the quantum cascade laser device 1 according to the first embodiment, and intersubband electron transition in a quantum well structure in the active layer 13.

FIG. 3 is a process chart for explanation of a manufacturing method of the quantum cascade laser device 1 according to the first embodiment.

FIG. 4 is a process chart for explanation of the manufacturing method of the quantum cascade laser device 1 according to the first embodiment.

FIG. 5 is a process chart for explanation of the manufacturing method of the quantum cascade laser device 1 according to the first embodiment.

FIG. 6 is a perspective view of a quantum cascade laser device 2 according to a second embodiment.

FIG. 7 is a process chart for explanation of a manufacturing method of the quantum cascade laser device 2 according to the second embodiment.

FIG. 8 is a process chart for explanation of the manufacturing method of the quantum cascade laser device 2 according to the second embodiment.

### DESCRIPTION OF THE PREFERRED EMBODIMENTS

Hereinafter, a preferred embodiment for carrying out the present invention will be described in detail with reference to the accompanying drawings. In the description of the drawings, the same or equivalent components are attached with the same reference numerals, and overlapping description will be omitted. The dimensional ratios of the drawings are not always equal to those of the description.

### First Embodiment

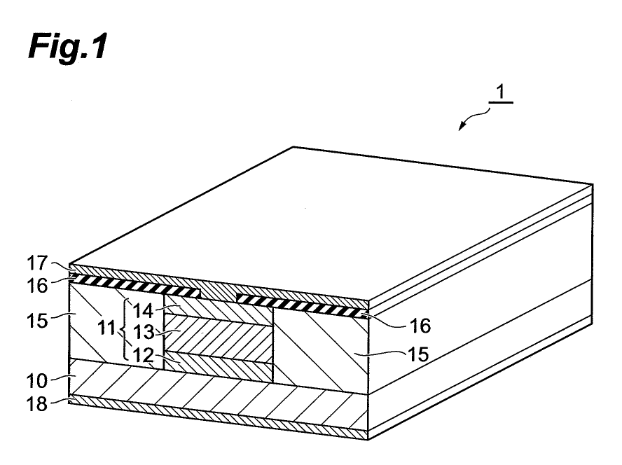

First, a first embodiment of a quantum cascade laser device according to the present invention will be described. FIG. 1 is a perspective view of a quantum cascade laser device 1 according to the first embodiment. In the quantum cascade laser device 1 shown in this figure, a laminate structure 11 is formed in a stripe shape along a predetermined direction on a principal surface at one side of a substrate 10, and insulating layers 15 are formed on the bilateral sides of the laminate structure 11, and an insulating layer 16 and a metal layer 17 are formed in sequence on the laminate structure 11 and the insulating layers 15. Further, a metal layer 18 is formed on a principal surface at the other side of the substrate 10. The both end faces of the laminate structure 11 serve as mirrors of a laser resonator.

The laminate structure 11 is formed such that a cladding layer 12, an active layer 13, and a cladding layer 14 are formed in sequence from the side of the substrate 10. In the active layer 13, light emitting layers and injection layers are alternately laminated, and the active layer 13 generates light due to intersubband electron transition in a quantum well structure. The insulating layer 16 has an opening above the cladding layer 14, and the metal layer 17 is electrically connected to the cladding layer 14 through the opening. This opening continues along the predetermined direction in which the laminate structure 11 is provided to extend. Each of the metal layer 17 and the metal layer 18 is used as an electrode to which a voltage is applied.

In particular, in the first embodiment, a shape of the laminate structure 11 in a cross section perpendicular to the direction in which the laminate structure 11 is provided to extend is made into a rectangle. Here, in some cases, a cross-sectional shape of the laminate structure 11 is not necessarily formed into an ideal rectangle due to the upper or lower corners being rounded. However, even in such a case, a cross-sectional shape of the active layer 13 included in the laminate structure 11 could be approximately formed into a more ideal rectangle.

One example of compositions in the respective layers is as follows. The substrate 10 is formed of InP. The cladding layers 12 and 14 are formed of InP or InAlAs. The active layer 13 is composed of a multiple quantum well structure of InGaAs/InAlAs. The insulating layers 15 are formed of Fe-doped InP. The insulating layers 15 may be formed of any material which is an insulating material with low thermal resistance. The insulating layer 16 is formed of SiN or SiO₂. The metal layer 17 is formed of Ti/Au. Further, the metal layer 18 is formed of AuGe/Au. Here, it is preferable that the substrate 10 is a (1, 0, 0) n-type InP substrate, and the direction in which the laminate structure 11 is provided to extend is a direction of [0, 1, −1] or a direction of [0, −1, 1] on the substrate 10.

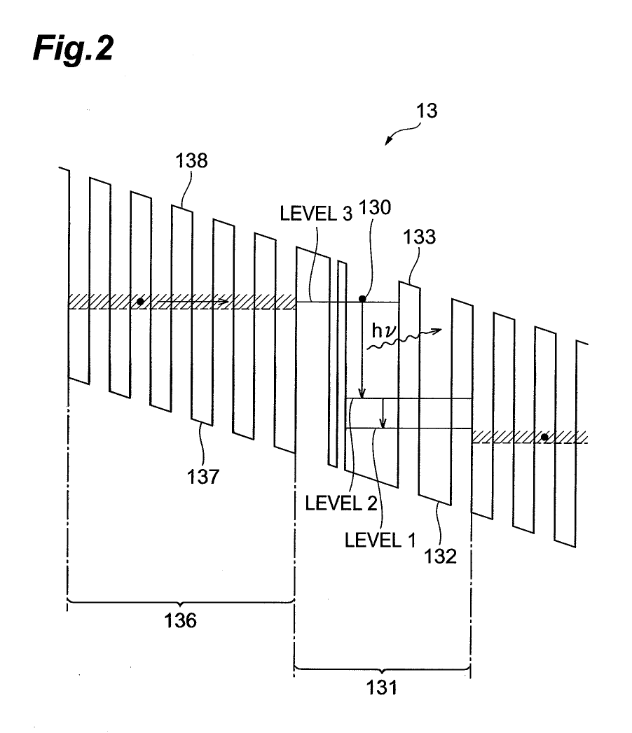

FIG. 2 is a schematic view for explanation of a configuration of the active layer 13 in the quantum cascade laser device 1 according to the first embodiment, and intersubband electron transition in the quantum well structure in the active layer 13. In this figure, the lateral direction corresponds to a direction of a thickness of the active layer 13, and the longitudinal direction corresponds to an energy level. Further, in this figure, for illustrative convenience, a laminated structure of a light emitting layer 131 and an injection layer 136 which are adjacent to one another in the multistage repeated structure of emitting layers and injection layers of the active layer 13 is shown.

As shown in FIG. 2, the light emitting layer 131 is formed of quantum well layers 132 and quantum barrier layers 133. The light emitting layer 131 is a portion functioning as an active region to generate light hv in a semiconductor laminated structure of the active layer 13. In FIG. 2, as the quantum well layers 132 in the emitting layer 131, three quantum well layers different from each other in thickness are shown. Further, in the emitting layer 131, three quantum levels of a level 1, a level 2, and a level 3 are formed in sequence from the bottom by the quantum well layers 132 and the quantum barrier layers 133. Further, the electron injection layer 136 is provided between the light emitting layer 131 and the next emitting layer. The injection layer 136 is formed of quantum well layers 137 and quantum barrier layers 138.

In the quantum cascade laser device 1, in a state in which a bias voltage is applied to the laminate structure 11 including the active layer 13 in such a quantum level structure, electrons 130 from the injection layer 136 are injected into the level 3 in the emitting layer 131. The electrons 130 injected into the level 3 are made to carry out emission transition to the level 2, and at this time, light hv having a wavelength corresponding to an energy level difference between the quantum levels of the level 3 and the level 2 is generated.

Further, the electrons 130 made to carry out transition to the level 2 are relaxed to the level 1 at high speed, and those are injected into the level 3 of the next emitting layer through the injection layer 136 in a cascading manner. By repeating such injections and emission transitions of electrons in the laminated structure of the active layer 13, production of light in a cascade manner is brought about in the active layer 13. That is, by laminating a large number of the emitting layers 131 and the injection layers 136 alternately as shown in FIG. 2, the electrons 130 are moved sequentially in a cascading manner in the emitting layers 131, and light hv is generated at the time of intersubband transition in each of the emitting layers 131. Further, when such a light is resonated in an optical resonator of the quantum cascade laser device 1, a laser light at a predetermined wavelength is generated.

In the laminate structure 11 of the quantum cascade laser device 1, as a waveguiding structure in which light generated in the active layer 13 with a cascading laminated structure shown in FIG. 2 is wave-guided in a direction of the resonator in the quantum cascade laser device 1, the cladding layer 12 and the cladding layer 14 providing the active layer 13 therebetween are provided.

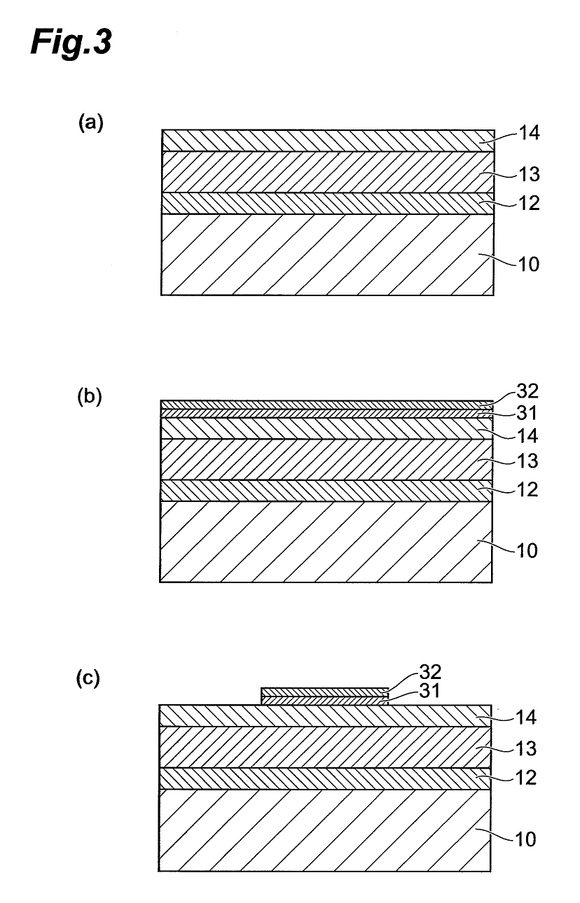

Next, an example as a method for manufacturing the quantum cascade laser device 1 according to the first embodiment will be described. FIG. 3 to FIG. 5 are process charts for explanation of the method for manufacturing the quantum cascade laser device 1 according to the first embodiment. Here, the compositions of the respective layers will be hereinafter described as described above.

First, the cladding layer 12 consisting of InP or InAlAs, the active layer 13 formed of a multiple quantum well structure of InGaAs/InAlAs, and the cladding layer 14 consisting of InP or InAlAs are formed in sequence by a molecular beam epitaxy (MBE) method or a metal-organic-vapor-phase epitaxy (MOVPE) method on the principal surface at one side of the (1, 0, 0) n-type InP substrate 10 ((a) in FIG. 3). Moreover, an insulating layer 31 is formed on the cladding layer 14, and a resist 32 is further applied thereto ((b) in FIG. 3). The insulating layer 31 is formed of, for example, SiN or SiO₂. Then, with respect to the insulating layer 31 and the resist 32, a portion of a region in a stripe shape with a predetermined width provided to extend in the direction of [0, 1, −1] or the direction of [0, −1, 1] on the substrate 10 is made to remain, and the other region is removed by photolithography and etching ((c) in FIG. 3).

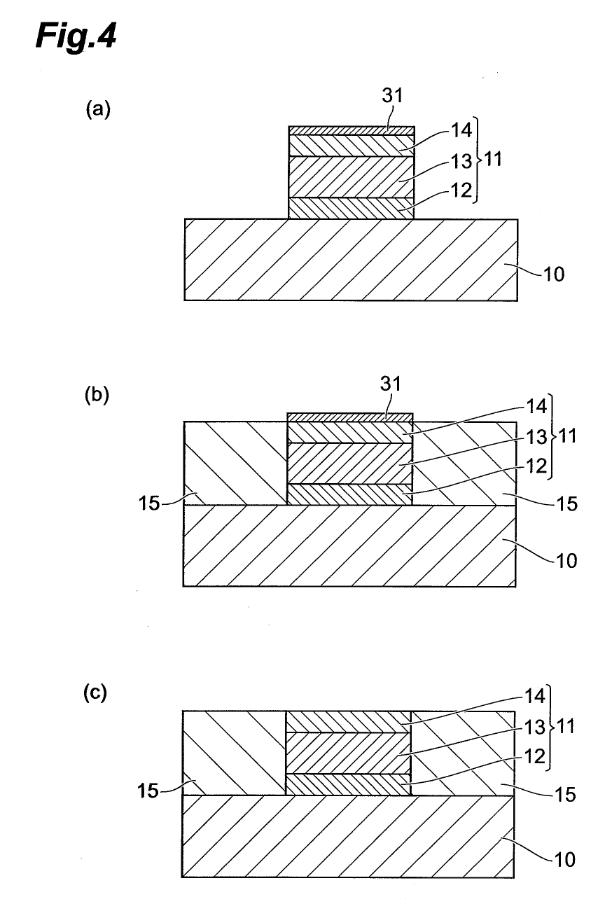

Dry etching is applied by using the insulating layer 31 and the resist 32 in a stripe shape with the predetermined width as a mask, and thereafter, the resist 32 is removed ((a) in FIG. 4). The cladding layer 12, the active layer 13, and the cladding layer 14 under the mask remain by this dry etching, and in accordance therewith, the laminate structure 11 which is a rectangle at a cross section is formed. As a dry etching method used at this time, for example, there is a reactive ion etching (RIE) method by use of a chlorine-based gas in a state in which it is heated to 200° C. or more in temperature, an RIE method by use of a methane-based gas at room temperature, an ion beam etching method by use of a chlorine-based gas at room temperature, and the like.

Subsequently, in a state in which the insulating layer 31 in a stripe shape with the predetermined width remaining on the cladding layer 14, the insulating layers 15 are formed on the principal surface of the substrate 10 on both sides of the laminate structure 11 by using the insulating layer 31 as a mask for selective embedding growth ((b) in FIG. 4). The insulating layers 15 consist of Fe-doped InP, and those are formed by an MOVPE method. The insulating layers 15 may be composed of any material which is an insulating material with low thermal resistance. The insulating layer 15 is required to have a thickness greater than or equal to a thickness into which the active layer 13 is buried, and preferably has a thickness which is not over the top surface of the insulating layer 31 as a mask. After the insulating layers 15 are formed, the insulating layer 31 serving as a mask is removed by etching ((c) in FIG. 4).

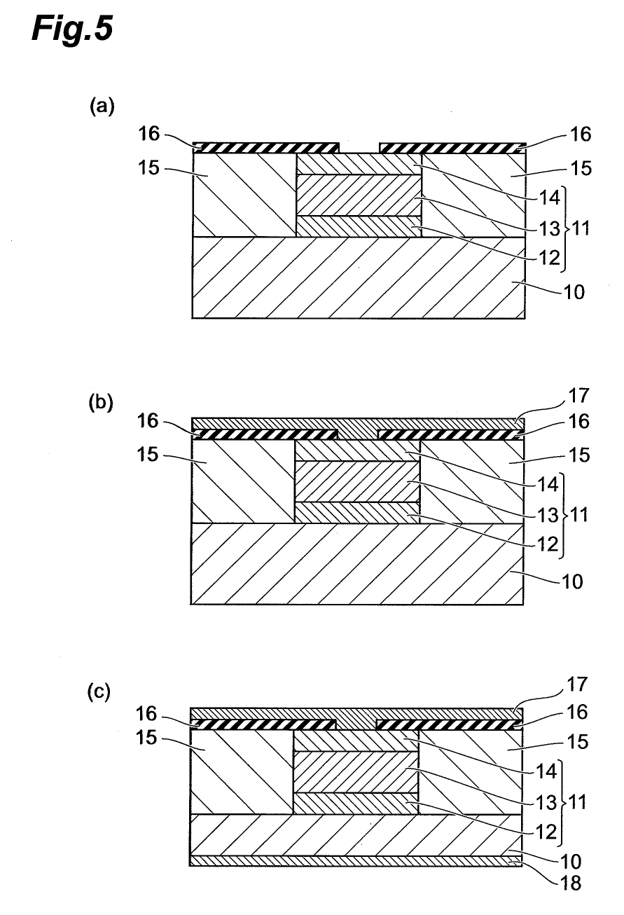

Furthermore, the insulating film 16 consisting of SiN or SiO₂ is formed on the cladding layer 14 and the insulating layers 15, and an opening is formed in the insulating film 16 by photolithography and etching ((a) in FIG. 5). Moreover, the metal layer 17 consisting of Ti/Au is formed on the insulating film 16 ((b) in FIG. 5). The opening of the insulating layer 16 continues in a direction in which the laminate structure 11 is provided to extend above the cladding layer 14, and the metal layer 17 is electrically connected to the cladding layer 14 through the opening. Further, the substrate 10 is made into a thin wall by grinding the bottom surface of the substrate 10, and the metal layer 18 consisting of AuGe/Au is formed on the bottom surface of the substrate 10 ((c) in FIG. 5). Then, the both end faces are formed due to cleavage, which serve as a laser resonator structure. At this time, one end face of the resonator may be coated with a high-reflective film of Au or the like.

In the quantum cascade laser device 1 according to the first embodiment manufactured as described above, because a shape in a cross section of the laminate structure 11 perpendicular to the direction in which the laminate structure 11 is provided to extend is made into a rectangle, as compared with a case of a normal mesa shape, the quantum cascade laser device 1 is efficient in its current confinement, which leads to high slope efficiency. Further, because a shape at a cross section of the laminate structure 11 is made into a rectangle, a width of the light emitting layers is narrowed, and spread of the emitting point is prevented, which makes it possible to stably obtain a beam profile in a single transverse mode. This is extremely important for a light source expected to be applied in the field of spectroscopic analysis.

Further, in the quantum cascade laser device 1 according to the first embodiment, because the insulating layers 15 with high thermal conductivity are provided on the bilateral sides of the laminate structure 11 including the active layer 13, heat generated in the active layer 13 during driving is radiated through the insulating layers 15, which improves the radiation performance. In accordance therewith, a highly efficient refractive index confinement is possible, and it is possible to realize a high-duty and continuous-wave (CW) high-power operation at a high temperature range.

Moreover, in the quantum cascade laser device 1 according to the first embodiment, because a direction in which the laminate structure 11 is provided to extend is the direction of [0, 1, −1] or the direction of [0, −1, 1] on the substrate 10, covering growth of the insulating layers 15 onto the laminate structure 11 during the selective buried growth thereof does not easily occur.

### Second Embodiment

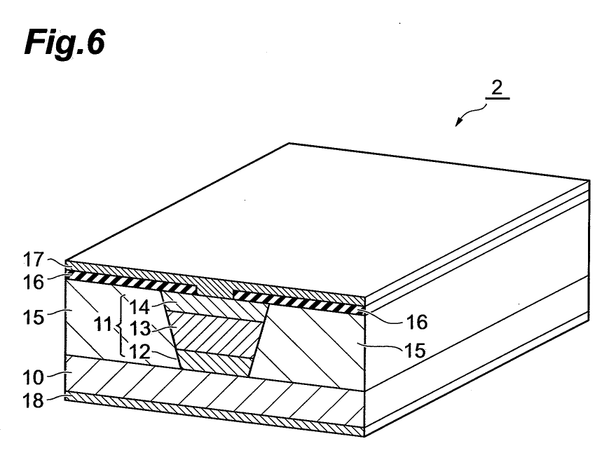

Next, a second embodiment of the quantum cascade laser device according to the present invention will be described. FIG. 6 is a perspective view of a quantum cascade laser device 2 according to the second embodiment. In the quantum cascade laser device 2 shown in this figure, the laminate structure 11 is formed in a stripe shape along a predetermined direction on a principal surface at one side of the substrate 10, and the insulating layers 15 are formed on the bilateral sides of the laminate structure 11, and the insulating layer 16 and the metal layer 17 are formed in sequence on the laminate structure 11 and the insulating layers 15. Further, the metal layer 18 is formed on a principal surface at the other side of the substrate 10. The both end faces of the laminate structure 11 serve as mirrors configuring a laser resonator.

The laminate structure 11 is formed such that the cladding layer 12, the active layer 13, and the cladding layer 14 are formed in sequence from the side of the substrate 10. In the active layer 13, light emitting layers and injection layers are alternately laminated, and the active layer 13 generates light due to intersubband electron transition in a quantum well structure. The insulating layer 16 has an opening above the cladding layer 14, and the metal layer 17 is electrically connected to the cladding layer 14 through the opening. This opening continues along the predetermined direction in which the laminate structure 11 is provided to extend. Each of the metal layer 17 and the metal layer 18 is used as an electrode to which a voltage is applied.

In particular, in the second embodiment, a shape of the laminate structure 11 in a cross section perpendicular to the direction in which the laminate structure 11 is provided to extend is formed into an inverted mesa shape. Here, in some cases, a cross-sectional shape of the laminate structure 11 is not necessarily made into an ideal inverted mesa shape due to the upper or lower corners being rounded. However, even in such a case, a cross-sectional shape of the active layer 13 included in the laminate structure 11 could be approximately formed into a more ideal inverted mesa shape.

One example of compositions in the respective layers is the same as that in the first embodiment. Further, the configuration of the active layer 13 in the quantum cascade laser device 2 according to the second embodiment, and intersubband electron transition in a quantum well structure of the active layer 13 as well is the same as that in the first embodiment described by use of FIG. 2.

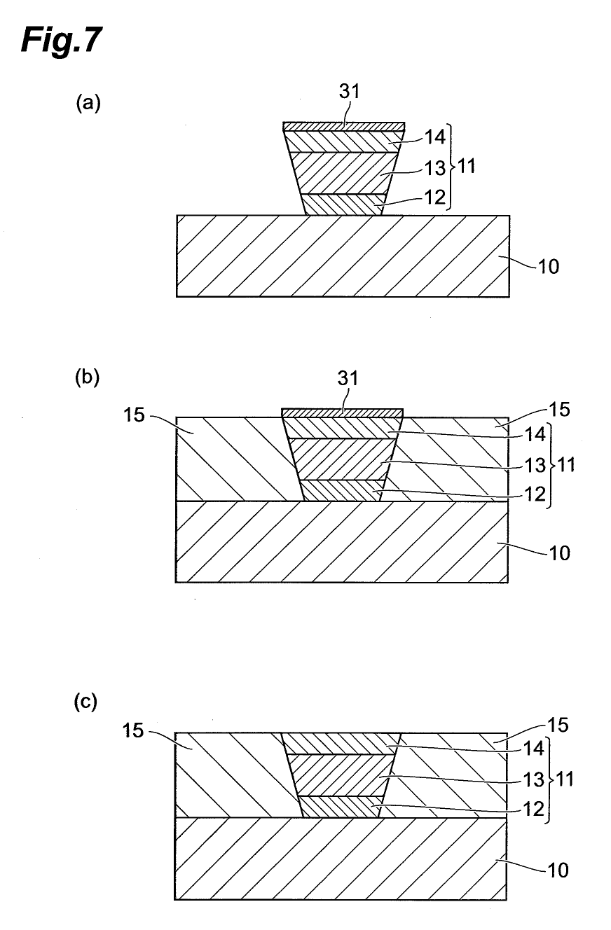

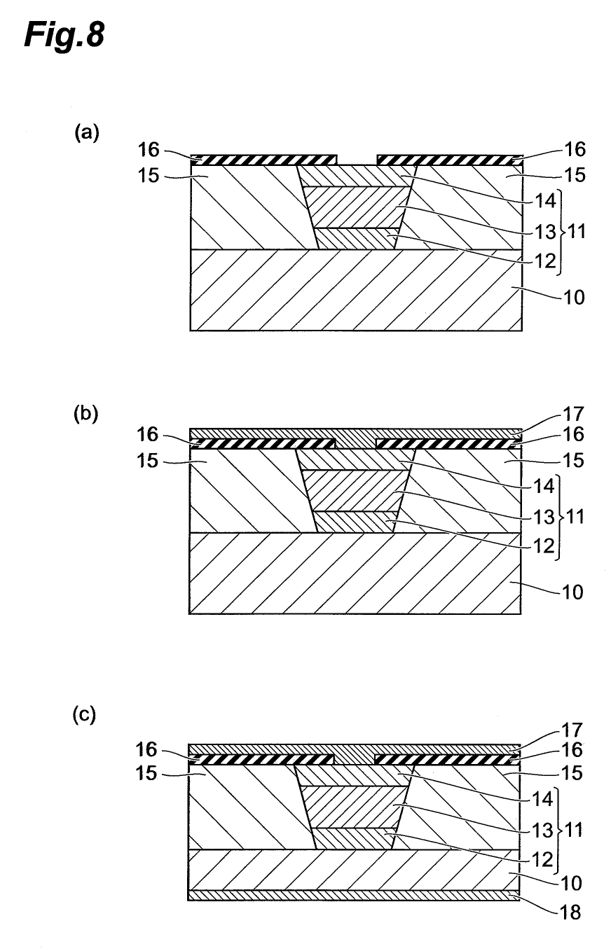

Next, an example as a method for manufacturing the quantum cascade laser device 2 according to the second embodiment will be described. FIG. 7 and FIG. 8 are process charts for explanation of the method for manufacturing the quantum cascade laser device 2 according to the second embodiment.

First, the cladding layer 12, the active layer 13, and the cladding layer 14 are formed in sequence on the principal surface at one side of the (1, 0, 0) n-type InP substrate 10, and the insulating layer 31 is further formed on the cladding layer 14, and the resist 32 is applied thereto. Then, with respect to the insulating layer 31 and the resist 32, a portion of a region in a stripe shape with a predetermined width provided to extend in the direction of [0, 1, −1] or the direction of [0, −1, 1] on the substrate 10 is made to remain, and the other region is removed. The processes so far are the same as those in the first embodiment described by use of (a) to (c) in FIG. 3.

Dry etching is applied by using the insulating layer 31 and the resist 32 in a stripe shape with the predetermined width as a mask, and thereafter, the resist 32 is removed ((a) in FIG. 7). The cladding layer 12, the active layer 13, and the cladding layer 14 under the mask remain by this dry etching, and in accordance therewith, the laminate structure 11 which is an inverted mesa shape at a cross section is formed. As a dry etching method used at this time, for example, ion beam etching with a tilt mechanism is preferably used, which makes it possible to realize the laminate structure 11 in an inverted mesa shape in a highly reproducible manner. The substrate 10 is tilted at, for example, about ±10° to a direction of an ion beam acceleration, centering on an axis of the direction in which the laminate structure 11 is provided to extend, and etching is applied thereto. By varying an angle during etching, a cross-sectional shape of the laminate structure 11 can be formed to be symmetric.

Subsequently, in a state in which the insulating layer 31 in a stripe shape with the predetermined width remaining on the cladding layer 14, the insulating layers 15 are formed on the principal surface of the substrate 10 on both sides of the laminate structure 11 by using the insulating layer 31 as a mask for selective embedding growth ((b) in FIG. 7). After the insulating layers 15 are formed, the insulating layer 31 as a mask is removed by etching ((c) in FIG. 7). Furthermore, the insulating film 16 is formed on the cladding layer 14 and the insulating layers 15, and an opening is formed in the insulating film 16 by photolithography and etching ((a) in FIG. 8). Moreover, the metal layer 17 is formed on the insulating film 16 ((b) in FIG. 8). Further, the substrate 10 is made into a thin wall by grinding the bottom surface of the substrate 10, and the metal layer 18 is formed on the bottom surface of the substrate 10 ((c) in FIG. 8). Then, the both end faces are formed due to cleavage, which serve as a laser resonator structure. Processes after (a) in FIG. 7 are the same as those in the first embodiment.

In the quantum cascade laser device 2 according to the second embodiment manufactured as described above, not only can effects which are identical to those in the first embodiment be carried out, but also because a shape in a cross section of the laminate structure 11 perpendicular to the direction in which the laminate structure 11 is provided to extend is made into an inverted mesa shape, the following effects as well can be carried out. That is, provided that a width of the insulating layer 31 serving as a mask is constant, because a shape at a cross section of the laminate structure 11 is made into an inverted mesa shape, as compared with a case of a rectangle, the quantum cascade laser device 2 is further efficient in its current confinement, which leads to high slope efficiency. Further, a width of the light emitting layers is narrowed, and spread of the emitting point is prevented, which makes it possible to stably obtain a beam profile in a single transverse mode.

The quantum cascade laser device according to the present invention has high slope efficiency, and can be utilized as a quantum cascade laser device capable of stably realizing a single transverse mode operation.

Here, in the quantum cascade laser device according to the above-described embodiments, a configuration is used in which the laminate structure including the active layer in which light emitting layers and injection layers are alternately laminated, and which generates light due to intersubband electron transition in a quantum well structure is formed into a stripe shape along a predetermined direction on the principal surface of the substrate, and a shape at a cross section of the laminate structure perpendicular to the predetermined direction is a rectangle or an inverted mesa shape, and the insulating layers are formed on the principal surface of the substrate and on the bilateral sides of the laminate structure.

Further, in the quantum cascade laser device having the above-described configuration, it is preferable that the substrate is a (1, 0, 0) InP substrate, and the predetermined direction is the direction of [0, 1, −1] or the direction of [0, −1, 1] on the substrate. In this case, covering growth of the insulating layers onto the laminate structure during selective embedding growth does not easily occur.

From the invention thus described, it will be obvious that the invention may be varied in many ways. Such variations are not to be regarded as a departure from the spirit and scope of the invention, and all such modifications as would be obvious to one skilled in the art are intended for inclusion in the scope of the following claims.

What is claimed is:

1. A quantum cascade laser device comprising:
a substrate; and
a laminate structure including an active layer in which light emitting layers and injection layers are alternately laminated, the active layer generates light due to intersubband electron transition in a quantum well structure, wherein
the laminate structure is formed in a stripe shape along a predetermined direction on a principal surface of the substrate, and a shape in a cross section of the laminate structure perpendicular to the predetermined direction is a rectangle or an inverted mesa shape, and
insulating layers are formed on the principal surface of the substrate and on bilateral sides of the laminate structure.

2. The quantum cascade laser device according to claim 1, wherein the substrate is a (1, 0, 0) InP substrate, and the predetermined direction is a direction of [0, 1, −1] or a direction of [0, −1, 1] on the substrate.
